(19) United States
(12) Patent Application Publication
(10) Pub. No.: US 2025/0046725 A1
(43) Pub. Date: Feb. 6, 2025

(54) SEMICONDUCTOR PACKAGE

(71) Applicant: SAMSUNG ELECTRO-MECHANICS CO., LTD., Suwon-si (KR)

(72) Inventors: Seok Hwan KIM, Suwon-si (KR); Chi Hyeon JEONG, Suwon-si (KR); Hyun Sang KWAK, Suwon-si (KR); Hyung Joon KIM, Suwon-si (KR); Jung Ho SHIM, Suwon-si (KR)

(73) Assignee: SAMSUNG ELECTRO-MECHANICS CO., LTD., Suwon-si (KR)

(21) Appl. No.: 18/766,911

(22) Filed: Jul. 9, 2024

(30) Foreign Application Priority Data
Aug. 1, 2023 (KR) 10-2023-0100614

(51) Int. Cl. H01L 23/538; H01L 23/00; H01L 23/31; H01L 23/528; H01L 25/18

(52) U.S. Cl. CPC H01L 23/5386; H01L 23/3121; H01L 23/5283; H01L 23/5381; H01L 24/08; H01L 24/16; H01L 24/32; H01L 24/73; H01L 25/18; H01L 24/13; H01L 2224/08225; H01L 2224/13111; H01L 2224/13124; H01L 2224/13147; H01L 2224/16225; H01L 2224/16245; H01L 2224/32225; H01L 2224/73204; H01L 2924/1431; H01L 2924/1436

(57) ABSTRACT

A semiconductor package includes: a package board; a first semiconductor chip disposed on the package board, and having a first recess portion adjacent to a first front surface of the first semiconductor chip facing the package board; a second semiconductor chip disposed side by side with the first semiconductor chip on the package board, and having a second recess portion adjacent to a second front surface of the second semiconductor chip facing the package board; and an interconnect bridge disposed on the first and second front surfaces, and at least partially disposed in each of the first and second recess portions.

### CROSS-REFERENCE TO RELATED APPLICATION(S)

This application claims benefit of priority to Korean Patent Application No. 10-2023-0100614 filed on Aug. 1, 2023 in the Korean Intellectual Property Office, the disclosure of which is incorporated herein by reference in its entirety.

### BACKGROUND

### 1. Field

The present disclosure relates to a semiconductor package.

### 2. Description of Related Art

As the numbers of central processing unit (CPU) and graphic processing unit (GPU) cores in server products are rapidly increased, die split technology for effectively increasing the number of cores is becoming popular. In addition, there is a need for technology for connecting die-to-die with a fine circuit line width in accordance with an increasing demand for a package including high bandwidth memory (HBM). To meet this technological demand, technology such as embedding a silicon bridge or technology using a silicon interposer has been developed. However, commercialization thereof has a limitation due to a price issue, a complex assembly process, or the like.

### SUMMARY

An aspect of the present disclosure may provide a semiconductor package including an interconnect bridge which has high degree of design freedom and may reduce an overall package thickness.

Another aspect of the present disclosure may provide a semiconductor package including an interconnect bridge that may be manufactured in a simple process and at low cost.

According to an aspect of the present disclosure, provided is a semiconductor package in which a recess portion is formed in each of a plurality of dies, a bridge interconnecting the plurality of dies is disposed in the recess portion, and the plurality of dies and the interconnect bridge in that state are mounted on a package board.

According to an aspect of the present disclosure, a semiconductor package may include: a package board; a first semiconductor chip disposed on the package board, and having a first recess portion adjacent to a first front surface facing the package board; a second semiconductor chip disposed side by side with the first semiconductor chip on the package board, and having a second recess portion adjacent to a second front surface facing the package board; and an interconnect bridge disposed on the first and second front surfaces, and at least partially disposed in each of the first and second recess portions.

According to another aspect of the present disclosure, a semiconductor package may include: a package board; first and second semiconductor chips disposed on the package board; a molding material disposed on the package board, and at least partially filling a space between the first and second semiconductor chips; a recess portion extending through a portion of each of the first and second semiconductor chips and the molding material in a vertical direction from a lower surface of each of the first and second semiconductor chips and the molding material; and an interconnect bridge disposed in the recess portion.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating a case in which a ball grid array (BGA) package is mounted on a main board of the electronic device;

FIG. 4 is a cross-sectional view schematically illustrating a case in which a silicon interposer package is mounted on the main board;

FIG. 5 is a cross-sectional view schematically illustrating a case in which an organic interposer package is mounted on the main board;

FIG. 6 is a cross-sectional view schematically illustrating an example of a semiconductor package;

FIG. 7 is an enlarged cross-sectional view schematically illustrating an example of region A of FIG. 6;

FIGS. 8A through 8E are process cross-sectional views schematically illustrating an example of manufacturing the semiconductor package of FIG. 6;

FIG. 9 is a cross-sectional view schematically illustrating another example of the semiconductor package; and

FIG. 10 is an enlarged cross-sectional view schematically illustrating an example of region B of FIG. 9.

### DETAILED DESCRIPTION

Hereinafter, exemplary embodiments of the present disclosure will now be described in detail with reference to the accompanying drawings.

### Electronic Device

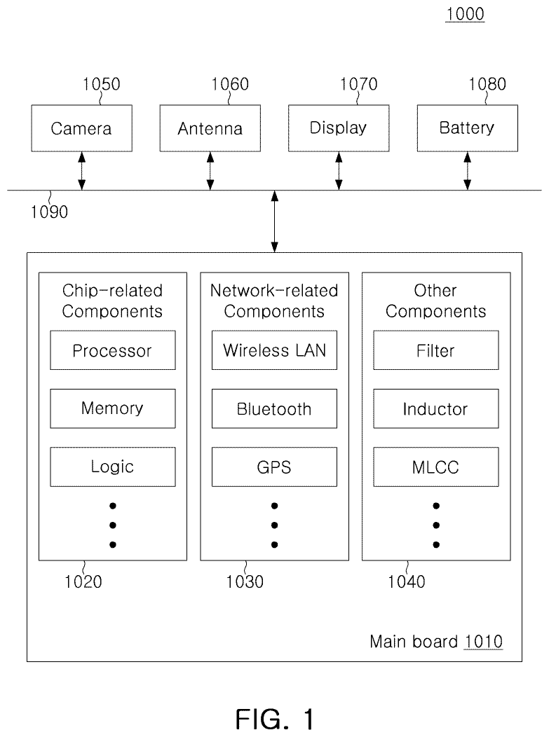

FIG. 1 is a block diagram schematically illustrating an example of an electronic device system.

Referring to the drawing, an electronic device 1000 may accommodate a main board 1010. The main board 1010 may include chip related components 1020, network related components 1030, other components 1040, and the like, physically or electrically connected thereto. These components may be connected to other electronic components described below to form various signal lines 1090.

The chip-related components 1020 may include: a memory chip such as a volatile memory (for example, a dynamic random access memory (DRAM)), a non-volatile memory (for example, a read only memory (ROM)), or a flash memory; an application processor chip such as a central processor (for example, a central processing unit (CPU)), a graphics processor (for example, a graphics processing unit (GPU)), a digital signal processor, a cryptographic processor, a microprocessor, or a microcontroller; and a logic chip such as an analog-to-digital (ADC) converter or an application-specific integrated circuit (ASIC). However, the chip-related components 1020 are not limited thereto, and may also include other types of chip-related components. In addition, the chip-related components 1020 may be combined with each other. The chip-related component 1020 may be a package including the above-mentioned chip or electronic component.

The network-related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the above-mentioned protocols. However, the network-related components 1030 are not limited thereto, and may also include any of various other wireless or wired standards or protocols. In addition, the network-related components 1030 may be combined with the chip-related components 1020.

The other components 1040 may include a high frequency inductor, a ferrite inductor, a power inductor, ferrite beads, low temperature co-firing ceramics (LTCC), an electro magnetic interference (EMI) filter, a multi-layer ceramic condenser (MLCC) and the like. However, the other components 1040 are not limited thereto, and may further include a passive element in a form of a chip component used for various other purposes in addition to these components. In addition, the other components 1040 may be combined with the chip-related components 1020 and/or the network-related components 1030.

The electronic device 1000 may include another electronic component that may be or may not be physically and/or electrically connected to the main board 1010, based on a type of the electronic device 1000. Another electronic component may be a camera module 1050, an antenna module 1060, a display 1070, a battery 1080, or the like. However, another electronic component is not limited thereto, and may be an audio codec, a video codec, a power amplifier, a compass, an accelerometer, a gyroscope, a speaker, a mass storage device (e.g., hard disk drive), a compact disk (CD), a digital versatile disk (DVD), or the like. In addition, another electronic component may be another electronic component used for various purposes, based on the type of the electronic device 1000.

The electronic device 1000 may be a smartphone, a personal digital assistant (PDA), a digital video camera, a digital still camera, a network system, a computer, a monitor, a tablet personal computer (PC), a laptop PC, a netbook PC, a television, a video game machine, a smartwatch, an automotive, or the like. However, the electronic device 1000 is not limited thereto, and may also be any other electronic device processing data.

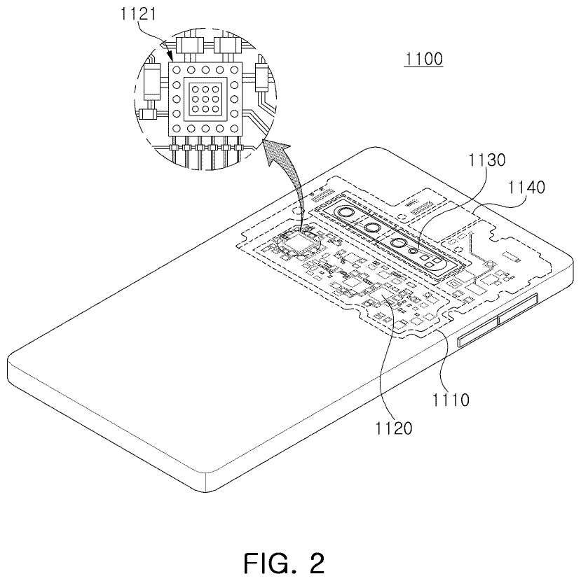

FIG. 2 is a perspective view schematically illustrating an example of the electronic device.

Referring to the drawing, the electronic device may be, for example, a smartphone 1100. The smartphone 1100 may accommodate a motherboard 1110, and various components 1120 may be physically and/or electrically connected to the motherboard 1110. In addition, the motherboard 1110 may accommodate other components that may be or may not be physically and/or electrically connected thereto, such as a camera module 1130 or a speaker 1140. Some of the components 1120 may be the chip-related components, for example, a component package 1121, and are not limited thereto. The component package 1121 may be in the form of a printed circuit board on which electronic components including active components and/or passive components are surface mounted. Alternatively, the component package 1121 may be in the form of a printed circuit board in which active components and/or passive components are embedded. Meanwhile, the electronic device is not necessarily limited to the smartphone 1100, and may be another electronic device as described above.

### Semiconductor Package Including Interposer

In general, numerous fine electrical circuits are integrated in a semiconductor chip. However, the semiconductor chip may not serve as a finished semiconductor product in itself, and may be damaged by external physical or chemical impacts. Therefore, the semiconductor chip itself may not be used, and may be packaged and used in the electronic device or the like, in a packaged state.

Here, semiconductor packaging is required due to a difference in a circuit width between the semiconductor chip and the main board of the electronic device in terms of electrical connections. In detail, a size of a contact pad of the semiconductor chip and a distance between the contact pads of the semiconductor chip are very fine. On the other hand, a size of component mounting pad of the main board used in the electronic device and a distance between the component mounting pads of the main board are significantly larger than those of the semiconductor chip. Therefore, it may be difficult to directly mount the semiconductor chip on the main board, thus requiring packaging technology for buffering the difference in the circuit width between the semiconductor chip and the main board.

Hereinafter, the description describes a semiconductor package including an interposer manufactured by this packaging technology in more detail with reference to the drawings.

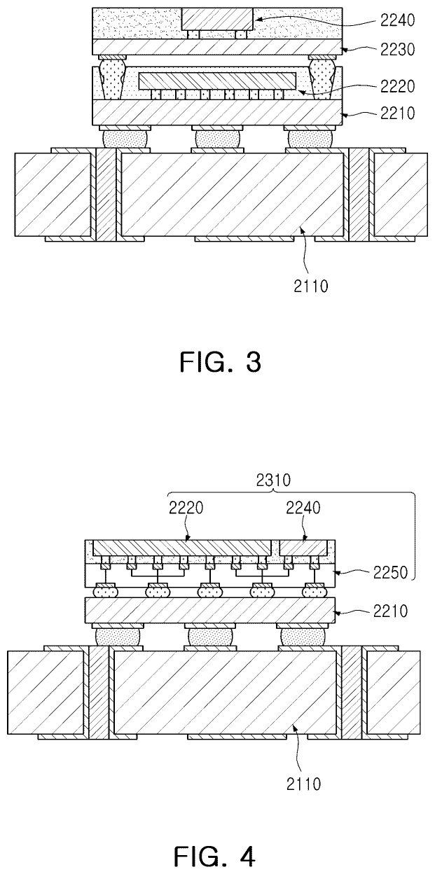

FIG. 3 is a cross-sectional view schematically illustrating a case in which a ball grid array (BGA) package is mounted on the main board of the electronic device.

An application specific integrated circuit (ASIC) such as a graphics processing unit (GPU) among the semiconductor chips is very expensive for each chip, and it is thus very important to perform the packaging on the ASIC at a high yield. For this purpose, a ball grid array (BGA) board 2210 or the like, which may redistribute several thousands to several hundreds of thousands of contact pads, may be first prepared before the semiconductor chip is mounted, and the semiconductor chip that is expensive, such as a GPU 2220, may be mounted and packaged on the BGA board 2210 by using surface mounting technology (SMT) or the like, and then be mounted finally on a main board 2110.

Meanwhile, the GPU 2220 may need to significantly reduce its signal path with a memory such as a high bandwidth memory (HBM). For this purpose, a product, in which a semiconductor chip such as an HBM 2240 is mounted on an interposer 2230, then packaged, and stacked on a package in which the GPU 2220 is mounted, in a package-on-package (POP) form, may be used. However, in this case, a device thickness may be excessively increased, and there is also a limit to significantly reducing the signal path.

FIG. 4 is a cross-sectional view schematically illustrating a case in which a silicon interposer package is mounted on the main board.

As a method for solving the problem described above, it may be considered to manufacture a semiconductor package 2310 including the silicon interposer by using interposer technology of surface-mounting and then packaging a first semiconductor chip such as the GPU 2220 and a second semiconductor chip such as the HBM 2240 side-by-side with each other on a silicon interposer 2250. In this case, the GPU 2220 and the HBM 2240 having several thousands to several hundreds of thousands of contact pads may be redistributed by the interposer 2250, and may be electrically connected to each other through the shortest path. In addition, the semiconductor package 2310 may be finally mounted on the main board 2110 when the semiconductor package 2310 including the silicon interposer is remounted on the BGA board 2210 or the like and redistributed.

However, it is very difficult to form a through-silicon via (TSV) in the silicon interposer 2250, and a cost required for manufacturing the silicon interposer 2250 is significantly high, and the silicon interposer 2250 is thus disadvantageous in increasing an area and reducing a cost.

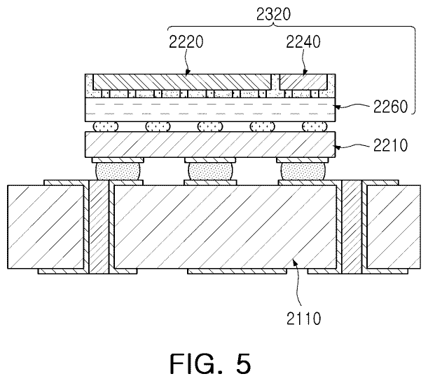

FIG. 5 is a cross-sectional view schematically illustrating a case in which an organic interposer package is mounted on the main board.

As a method for solving the problem described above, it may be considered to use an organic interposer 2260 instead of the silicon interposer 2250. For example, it may be considered to manufacture a semiconductor package 2320 including the organic interposer by using interposer technology of surface-mounting and then packaging the first semiconductor chip such as the GPU 2220 and the second semiconductor chip such as the HBM 2240 side-by-side with each other on the organic interposer 2260. In this case, the GPU 2220 and the HBM 2240 having several thousands to several hundreds of thousands of contact pads may be redistributed by the interposer 2260, and may be electrically connected to each other through the shortest path. In addition, the semiconductor package 2320 may be finally mounted on the main board 2110 when the semiconductor package 2320 including the organic interposer is remounted on the BGA board 2210 or the like and redistributed. In addition, the organic interposer may be advantageous in increasing an area and reducing a cost.

However, when using the organic interposer 2260, the semiconductor chips 2220 and 2240 may also be mounted on the organic interposer 2260, and then remounted on the BGA board 2210. Accordingly, a manufacturing process of the semiconductor package may be somewhat complicated, and there is a risk that a packaging yield is reduced.

### Semiconductor Package Including Bridge

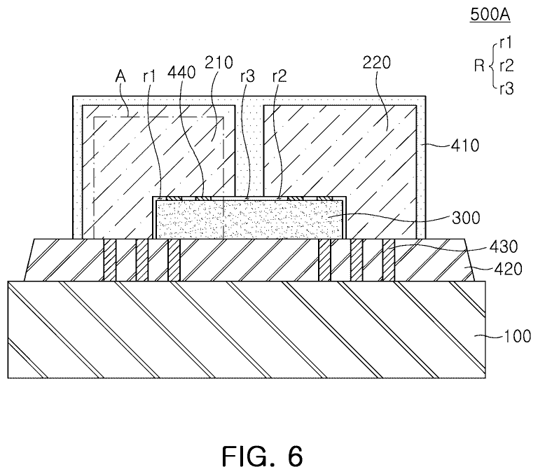

FIG. 6 is a cross-sectional view schematically illustrating an example of a semiconductor package.

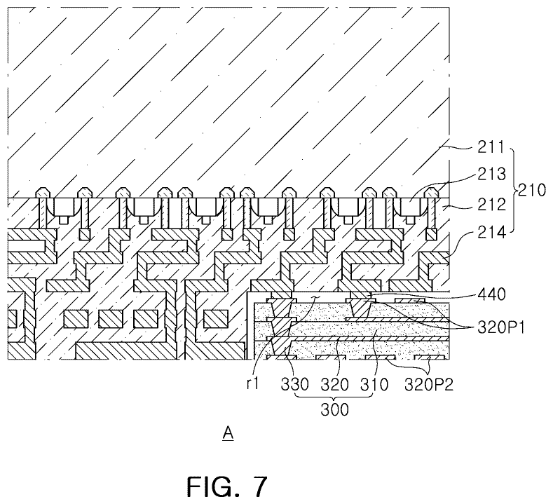

FIG. 7 is an enlarged cross-sectional view schematically illustrating an example of region A of FIG. 6.

Referring to the drawings, a semiconductor package 500A according to an exemplary embodiment may include: a package board 100; first and second semiconductor chips 210 and 220 disposed on the package board 100; a molding material 410 disposed on the package board 100 and at least partially filling a space between the first and second semiconductor chips 210 and 220; a recess portion R formed in the first and second semiconductor chips 210 and 220 and the molding material 410; an interconnect bridge 300 disposed in the recess portion R; a plurality of first contact members 430 connecting the package board 100 to the first and second semiconductor chips 210 and 220 and/or the package board 100 to the interconnect bridge 300; a plurality of second contact members 440 respectively connecting the interconnect bridge 300 to the first and second semiconductor chips 210 and 220; and an insulating material 420 having at least a portion disposed between the molding material 410, the first or second semiconductor chip 210 or 220, or the interconnect bridge 300 and the package board 100, and embedding the plurality of first contact members 430.

As described above, the semiconductor package 500A according to an exemplary embodiment may be mounted on the package board 100 while the interconnect bridge 300 is attached to each of first and second front surfaces of the first and second semiconductor chips 210 and 220. Compared to the case of embedding the interconnect bridge 300 in the package board 100, the semiconductor package 500A has a superior design space to increase its design freedom and may be manufactured in a simpler process and at a low cost. In addition, the recess portion R may be formed in the first and second semiconductor chips 210 and 220 and the molding material 410, and the interconnect bridge 300 may be disposed in the recess portion R, which may lower an overall thickness of the package.

Meanwhile, the recess portion R may include first to third recess portions r1, r2, and r3. The first recess portion r1 may be adjacent to the first front surface of the first semiconductor chip 210 that faces the package board 100. The second recess portion r2 may be adjacent to the second front surface of the second semiconductor chip 220 that faces the package board 100. The third recess portion r3 may be disposed in the bottom of the molding material 410 disposed between the first and second semiconductor chips 210 and 220. The first and second recess portions r1 and r2 may respectively extend through portions of the first and second semiconductor chips 210 and 220 from the first and second front surfaces in a vertical direction. The first and second recess portions r1 and r2 may respectively be exposed from inner surfaces of the first and second semiconductor chips 210 and 220 facing each other in a horizontal direction. The first and second recess portions r1 and r2 may be connected to each other through the third recess portion r3. In this way, the recess portion R may include the first to third recess portions r1, r2, and r3 respectively formed in the first and second semiconductor chips 210 and 220 and the molding material 410. Therefore, the recess portion R may have a bottom surface including the lower surface of each of the first and second semiconductor chips 210 and 220 and the molding material 410, and a wall surface including the inner surface of each of the first and second semiconductor chips 210 and 220. Here, the bottom surface of the recess portion R may be substantially flat. Therefore, the interconnect bridge 300 may be more easily disposed in the recess portion R, and may be more easily connected to each of the first and second semiconductor chips 210 and 220.

Meanwhile, the molding material 410 may cover the upper and/or outer surfaces of each of the first and second semiconductor chips 210 and 220, and the lower surface of the molding material 410 may have a step by the third recess portion r3. In more detail, the lower surface of a region of the molding material 410 that covers the outer surface of each of the first and second semiconductor chips 210 and 220 may be disposed at a level different from a level of the lower surface of the region of the molding material 410 that is disposed between the first and second semiconductor chips 210 and 220. For example, the lower surface of the former region may be disposed to be lower than the lower surface of the latter region. Therefore, the molding material 410 may not unnecessarily fill the recess portion R.

Meanwhile, the interconnect bridge 300 may include an organic insulating layer 310, a plurality of metal wiring layers 320 respectively disposed on or in the organic insulating layer 310, and at least one metal via layer 330 disposed in the organic insulating layer 310 and connecting the plurality of metal wiring layers 320 to each other. For example, the interconnect bridge 300 may be an organic bridge. For example, the interconnect bridge 300 may be a high-density printed circuit board including a microcircuit. Therefore, the process simplification and cost reduction may be possible compared to when the interconnect bridge 300 uses the silicon bridge. However, if necessary, the interconnect bridge 300 may use the silicon bridge instead of the organic bridge.

Hereinafter, the description describes components of the semiconductor package 500A according to an exemplary embodiment in more detail with reference to the drawings.

The package board 100 may be an organic board or a silicon board, and may be an organic board. The organic board may be a core type printed circuit board, a coreless type printed circuit board, or the like, and is not limited thereto. The organic board may have any of various forms such as a rigid printed circuit board, a flexible printed circuit board, and a rigid-flexible printed circuit board. The organic board may include a plurality of insulating layers, a plurality of wiring layers respectively disposed on or in the plurality of insulating layers, and a plurality of via layers each extending through at least one of the plurality of insulating layers. The organic board may further include a solder resist layer disposed on the outermost side of the plurality of insulating layers.

The plurality of insulating layers may each include an insulating material. The insulating material may use a thermosetting resin such as an epoxy resin or a thermoplastic resin such as polyimide, a material in which this insulating resin is mixed with an inorganic filler such as silica, a resin impregnated into a core material such as a glass fiber (i.e., glass fiber, glass cloth, or glass fabric) together with the inorganic filler, for example, an insulating material of copper clad laminate (CCL), an Ajinomoto build-up film (ABF), a prepreg, or the like, and is not limited thereto. The plurality of insulating layers may have distinct boundaries or, if necessary, may not have distinct boundaries. For example, the insulating layers including substantially the same insulating material may have ambiguous boundaries. However, the boundaries of the insulating layer including different insulating materials may be more easily distinguished from each other. However, the boundary is not necessarily limited thereto, and may be clear regardless of the insulating material.

The plurality of wiring layers may each include a metal material. The metal material may use copper (Cu), aluminum (Al), silver (Ag), tin (Sn), gold (Au), nickel (Ni), lead (Pb), titanium (Ti), or an alloy thereof. The plurality of wiring layers may each include an electroless plating layer (or a chemical copper) and an electrolytic plating layer (or an electrolytic copper). If necessary, each of the plurality of wiring layers may further include a copper foil. The plurality of wiring layers may perform various functions based on respective designs of the corresponding layers. For example, the plurality of wiring layers may include a ground pattern, a power pattern, a signal pattern, or the like. Here, the signal pattern may include various signals other than the ground pattern, the power pattern, or the like, for example, a data signal. Each of these patterns may include a line pattern, a plane pattern, and/or a pad pattern.

The plurality of via layers may each include the metal material. The metal material may use copper (Cu), aluminum (Al), silver (Ag), tin (Sn), gold (Au), nickel (Ni), lead (Pb), titanium (Ti), or an alloy thereof. The plurality of via layers may each include the electroless plating layer (or the chemical copper) and the electrolytic plating layer (or the electrolytic copper). The plurality of via layers may perform various functions based on the respective designs of the corresponding layers. For example, the plurality of via layers may include a ground via, a power via, a signal via, or the like. In the plurality of via layers, each via may be a field type in which the metal material fills a via hole, is not limited thereto, and may be a conformal type in which the metal material is disposed along a wall surface of the via hole. In the plurality of via layers, each via may have various shapes such as cylindrical, hourglass, and tapered shapes.

The solder resist layer may protect an internal component of the package board 100. A material of the solder resist layer is not particularly limited. For example, the solder resist layer may use the insulating material, and in this case, the insulating material may use solder resist. However, a material of the solder resist layer is not limited thereto, and may use ABF or the like.

A plurality of pads connected to the plurality of first contact members 430 may be disposed on the top of the package board 100. The plurality of pads may be embedded in an upper surface of the package board 100, or may protrude from the upper surface of the package board 100. Each of the plurality of pads may include the metal material such as copper (Cu), aluminum (Al), silver (Ag), tin (Sn), gold (Au), nickel (Ni), lead (Pb), titanium (Ti), or an alloy thereof. The plurality of pads may include the electroless plating layer (or the chemical copper) and the electrolytic plating layer (or the electrolytic copper). If necessary, each of the plurality of pads may further include the copper foil. The plurality of pads may include a ground pad, a power pad, a signal pad, or the like.

Each of the first and second semiconductor chips 210 and 220 may include an integrated circuit (IC) die in which hundreds to millions of elements or more are integrated into one chip. In this case, the IC may be, for example, the central processor (for example, the central processing unit (CPU)), the graphic processor (for example, the graphics processing unit (GPU)), a field programmable gate array (FPGA), the digital signal processor, the cryptographic processor, the micro processor, the micro controller, the application processor (eg, AP), an analog-to-digital converter, or the logic chip such as the application-specific IC (ASIC), and is not limited thereto. The IC may be a memory chip such as the volatile memory (for example, the dynamic random access memory (DRAM)), the non-volatile memory (for example, the read only memory (ROM)), the flash memory, or the high bandwidth memory (HBM), or another type such as a power management IC (PMIC).

The first and second semiconductor chips 210 and 220 may each be formed on the basis of an active wafer. In this case, a base material of each body of the first and second semiconductor chips 210 and 220 may be silicon (Si), germanium (Ge), gallium arsenide (GaAs), or the like. Various circuits may be formed on the body. The contact pad may be formed on each body, and the contact pad may include a conductive material such as aluminum (Al) or copper (Cu). The first and second semiconductor chips 210 and 220 may each be bare dies, in which case a metal bump may be disposed on the contact pad, if necessary. The first and second semiconductor chips 210 and 220 may each be packaged dies, in which case an additional redistribution layer may be formed on the contact pad, and the metal bump may be disposed on the redistribution layer, if necessary.

Each surface of the first and second semiconductor chips 210 and 220, where a first or second contact pad “P” is formed, may be an active surface, for example, a front surface of the semiconductor chip, and its opposite surface may be an inactive surface, for example, a back surface of the semiconductor chip. The first or second recess portion r1 or r2 may be adjacent to the active surface, for example, the front surface, of the first or second semiconductor chip 210 or 220.

For example, the first semiconductor chip 210 may include a first semiconductor board 211, a plurality of first transistor elements 213 disposed on the first semiconductor board 211, a first insulating layer 212 disposed on the first semiconductor board 211, and a plurality of first metal layers 214 respectively disposed on or in the first insulating layer 212. The plurality of first metal layers 214 may include a plurality of first contact pads P, each of which is at least partially exposed from a lower surface of the first insulating layer 212.

The first semiconductor board 211 may include a semiconductor material, such as a group IV semiconductor, a group III-V compound semiconductor, or a group II-VI oxide semiconductor. For example, the group IV semiconductor may include silicon, germanium, or silicon-germanium. The first semiconductor board 211 may be, for example, a bulk wafer, an epitaxial layer, a silicon on insulator (SOI) layer, or a semiconductor on insulator (SeOI) layer, and is not limited thereto.

The first transistor element 213 may include a gate insulating layer, a gate electrode, a capping layer, a spacer, or the like. Source/drain regions may be disposed on both sides of the first transistor element 213. The first transistor element 213 may be disposed in a cell region, and may include, for example, a DRAM memory element, a flash memory element, or a complementary metal oxide semiconductor (CMOS) image sensor (CIS) element, is not limited thereto, and may also include another logic element, a power element, or the like.

The first insulating layer 212 may include oxide, nitride, or oxynitride, for example, silicon oxide, silicon nitride, or silicon oxynitride, and is not limited thereto. The first insulating layer 212 may include a plurality of interlayer insulating layers, and each layer may include the same material or different materials. If necessary, an interlayer insulating film may be disposed between the interlayer insulating layers, and a protection layer may be disposed on the interlayer insulating layer.

The first metal layer 214 may include, for example, a low-resistance conductive material such as copper (Cu), aluminum (Al), or tungsten (W). Each layer of the first metal layers 214 may include the same material or a different material. Each layer of the first metal layers 214 may include a trace pattern, a via pattern, or the like. The trace pattern may include the pad pattern connected to the via pattern. The first metal layer 214 may be surrounded by an anti-diffusion layer. The anti-diffusion layer may include at least one material selected from the group consisting of titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boron (NiB). The anti-diffusion layer may further include a plug, if necessary, and the plug may be electrically connected to the first transistor element 213 and the first metal layer 214. The plug may include copper (Cu), tungsten (W), or a combination thereof.

The second semiconductor chip 220 may also include a second semiconductor board, a plurality of second transistor elements disposed on the second semiconductor board, a second insulating layer disposed on the second semiconductor board, and a plurality of second metal layers respectively disposed on or in the second insulating layer. In addition, the plurality of second metal layers may also include a plurality of second contact pads, each of which is at least partially exposed from a lower surface of the second insulating layer. A detailed description of the second semiconductor chip 220 is substantially the same as that of the first semiconductor chip 210.

The first and second semiconductor chips 210 and 220 may be mounted on the package board 100 by using the plurality of first contact members 430. For example, some of the plurality of first and second contact pads P of the first and second semiconductor chips 210 and 220 may each be connected to the package board 100 by using the plurality of first contact members 430. Each of the plurality of first contact members 430 may include a metal post, for example a copper pillar. Each of the plurality of first contact members 430 may further include a low-melting point metal, for example, solder including tin (Sn), aluminum (Al), copper (Cu), or the like, disposed on the metal post.

The interconnect bridge 300 may include the microcircuit for interconnection between the first and second semiconductor chips 210 and 220, in more detail, the microcircuit for die-to-die interconnection. For example, the interconnect bridge 300 may include an organic insulating layer 310, a plurality of metal wiring layers 320 respectively disposed on or in the organic insulating layer 310, and at least one metal via layer 330 disposed in the organic insulating layer 310 and connecting the plurality of metal wiring layers 320 to each other. For example, the interconnect bridge 300 may be the organic bridge. For example, the interconnect bridge 300 may be the high-density printed circuit board including the microcircuit. However, if necessary, the interconnect bridge 300 may use the silicon bridge instead of the organic bridge.

The organic insulating layer 310 may include an organic insulating material. The organic insulating material may use a thermosetting resin such as an epoxy resin, a thermoplastic resin such as polyimide, or these resins mixed with an inorganic filler such as silica, or a resin impregnated into the core material of the inorganic filler, such as prepreg or ABF, FR-4, or bismaleimide triazine (BT), and is not limited thereto. The number of layers of the organic insulating layer 310 is not particularly limited, and may be changed based on the design. The organic insulating layers 310 may have distinct boundaries, or may be integrated with each other to an extent that their boundaries are ambiguous.

The metal wiring layer 320 may include wiring for power transmission, wiring for signal transmission, wiring for ground transmission, or the like. Each of these wirings may include the trace pattern, the pad pattern, or the like. The metal wiring layer 320 may include a conductive material such as copper (Cu), aluminum (Al), silver (Ag), tin (Sn), gold (Au), nickel (Ni), lead (Pb), titanium (Ti), or an alloy thereof, and specifically include the metal material. The metal wiring layers 320 may include the electroless plating layer (or the chemical copper) and the electrolytic plating layer (or the electrolytic copper). The metal wiring layers 320 disposed on the uppermost and lowermost sides among the metal wiring layers 320 may include a plurality of first and second connection pads 320P1 and 320P2, respectively.

The metal via layer 330 may include a via for power transmission, a via for signal transmission, a via for ground transmission, or the like. Each of these vias may include the via pattern, or the like. The metal via layer 330 may include a conductive material such as copper (Cu), aluminum (Al), silver (Ag), tin (Sn), gold (Au), nickel (Ni), lead (Pb), titanium (Ti), or an alloy thereof. In detail, the metal via layer 330 may include the metal material. The metal via layers 330 may include the electroless plating layer (or the chemical copper) and the electrolytic plating layer (or the electrolytic copper). The via pattern of the metal via layer 330 may be tapered to the bottom based on its cross section, and is not limited thereto. The via pattern of the metal via layer 330 may include a micro via. The via pattern of the metal via layer 330 may include a filed via and/or a conformal via. The via pattern of the metal via layer 330 may include a stacked via and/or a staggered via.

The interconnect bridge 300 may be attached to the first and second semiconductor chips 210 and 220 by using the plurality of second contact members 440. For example, some other portions of the plurality of first and second contact pads P may respectively be connected to the plurality of first connection pads 320P1 of the interconnect bridge 300 by using the plurality of second contact members 440. Each of the plurality of second contact members 440 may include the metal bump and/or a solder bump. The second contact member 440 may include, for example, only the metal bump, only the solder bump, or both the metal bump and the solder bump. The metal bump may include copper (Cu), the solder bump may include solder, and are not limited thereto. The interconnect bridge 300 may be mounted on the package board 100 by using the plurality of first contact members 430. The plurality of second connection pads 320P2 of the interconnect bridge 300 may be connected to the package board 100 by using the plurality of first contact members 430 described above.

The molding material 410 may protect the first and second semiconductor chips 210 and 220. The molding material 410 may fill a space between the first and second semiconductor chips 210 and 220, and cover each of the upper and outer surfaces of the first and second semiconductor chips 210 and 220. The molding material 410 is not limited to any particular material, and may use an epoxy molding compound (EMC) for example.

The insulating material 420 may attach the first or second semiconductor chip 210 or 220 or the interconnect bridge 300 to the package board 100, and protect the plurality of first contact members 430. The insulating material 420 may at least partially fill a space between the molding material 410, the first or second semiconductor chip 210 or 220, or the interconnect bridge 300 and the package board 100, and embed and/or cover the plurality of first contact members 430. In one embodiment, at least some other portions of the plurality of first and second contact pads P and the plurality of second connection pads 320P2 may be disposed on the same surface of the insulating material 420. The insulating material 420 is not limited to any particular material, and may use a non conductive film (NCF) for example.

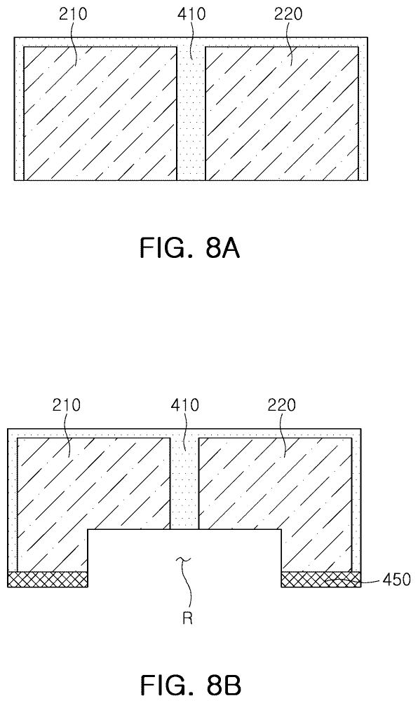

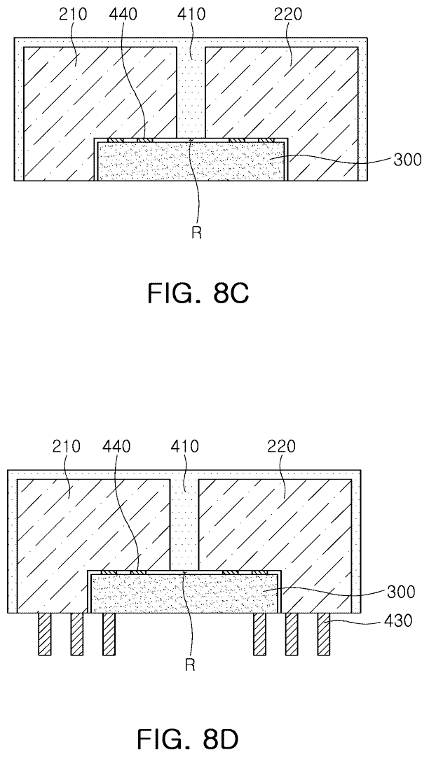

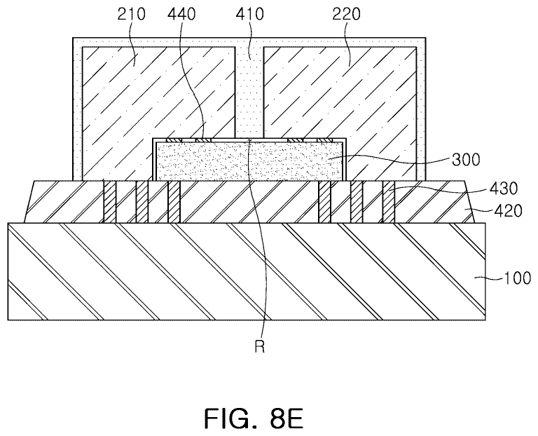

FIGS. 8A through 8E are process cross-sectional views schematically illustrating an example of manufacturing the semiconductor package of FIG. 6.

Referring to FIG. 8A, the first and second semiconductor chips 210 and 220 may be prepared, and the first and second semiconductor chips 210 and 220 may then be covered with the molding material 410.

Referring to FIG. 8B, a mask 450 may be used to form the recess portion R that passes through a portion of each of the first and second semiconductor chips 210 and 220 and the molding material 410. The recess portion R may be formed by etching or laser processing. Alternatively, the recess portion R may be formed using a grinding process. If necessary, a stopper layer for forming the recess portion R may exist in the first and second semiconductor chips 210 and 220. The recess portion R may include the first to third recess portions r1, r2, and r3 described above.

Referring to FIG. 8C, the interconnect bridge 300 may be manufactured and prepared in a separate process, and then disposed in the recess portion R. Here, the interconnect bridge 300 may be connected to the first and second semiconductor chips 210 and 220 by using the plurality of second contact members 440.

Referring to FIG. 8D, the plurality of first contact members 430 may be formed on the first and second semiconductor chips 210 and 220 and the interconnect bridge 300.

Referring to FIG. 8E, the plurality of first contact members 430 may be used to mount the first and second semiconductor chips 210 and 220 and the interconnect bridge 300 on the package board 100, and the insulating material 420 may be used to attach and/or secure the first and second semiconductor chips 210 and 220 and the interconnect bridge 300 to the package board 100.

The semiconductor package 500A according to an exemplary embodiment described above may be manufactured through a series of processes, and other contents are substantially the same as those described above.

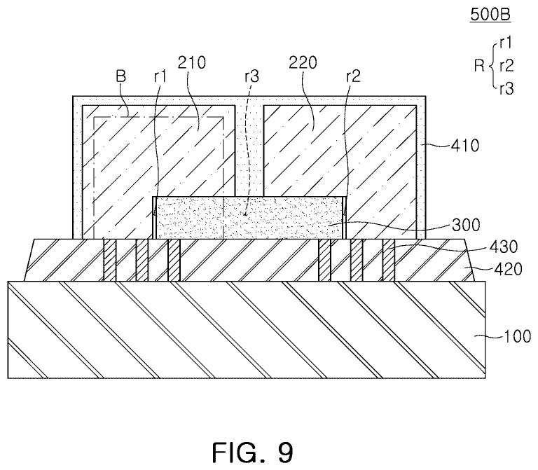

FIG. 9 is a cross-sectional view schematically illustrating another example of the semiconductor package.

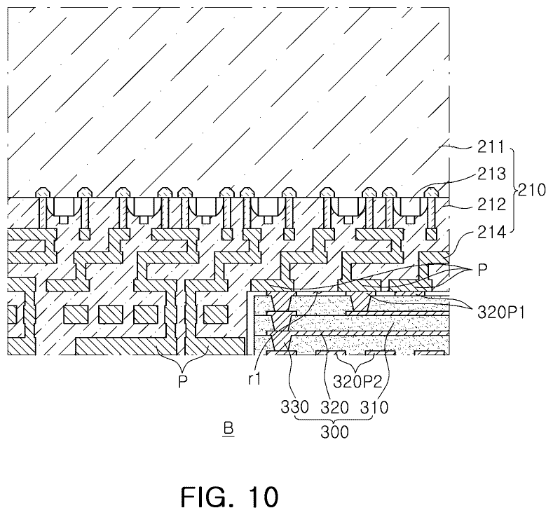

FIG. 10 is an enlarged cross-sectional view schematically illustrating an example of region B of FIG. 9.

Referring to the drawings, in a semiconductor package 500B according to another exemplary embodiment, the interconnect bridge 300 may be directly connected to each of the first and second semiconductor chips 210 and 220 as in the semiconductor package 500A according to an exemplary embodiment described above. The interconnect bridge 300 may be in direct contact with each of the first and second semiconductor chips 210 and 220 through a recessed surface of the first or second recess portion r1 or r2. For example, the plurality of first connection pads 320P1 of the interconnect bridge 300 may respectively be directly connected to some other portions of the plurality of first and second contact pads P of the first and second semiconductor chips 210 and 220. For example, the first connection pad 320P1 of the interconnect bridge 300 and the contact pad P of the semiconductor chip may be directly connected to each other by using pad-to-pad direct bonding, and are not limited thereto. In other words, at least some portions of the plurality of first and second contact pads P may be in direct contact with the plurality of first connection pads 320P1, respectively, of the interconnect bridge 300. A process other than the above-mentioned process is substantially the same as that described above.

As set forth above, the present disclosure may provide the semiconductor package including the interconnect bridge that has the high design freedom and may reduce the package thickness.

The present disclosure may provide the semiconductor package including the interconnect bridge that may be manufactured in the simple process and at the low cost.

In the present disclosure, the expression, “covering,” may include not only a case of entirely covering an object but also a case of partially covering the object, and may also include indirect covering as well as direct covering. In addition, the expression, “filling” may include not only complete filling an object but also approximate filling the object, for example, include a case in which the object has some pore spaces or voids.

In the present disclosure, the expression, “substantially,” may be determined by including a process error, a positional deviation, an error in measurement, and the like that occur in the manufacturing process. For example, the expression, “substantially flat,” may include not only completely flat, but also approximately flat.

In the present disclosure, the expression, “based on its cross section,” may indicate a cross-sectional shape of an object when the object is vertically cut or its cross-sectional shape when the object is viewed from a side. In addition, the expression, “on a plane” may indicate a shape of an object when the object is horizontally cut, or its planar shape when the object is viewed from top or bottom.

In the present disclosure, the expression, the “vertical direction,” indicates an up-down direction based on the cross section of the drawing for convenience, and the expression, the “vertical direction,” indicates a left-right direction based on the cross section of the drawing for convenience. In addition, a term the “bottom,” the “lower portion,” the “lower surface,” or the like, indicates a downward direction based on the cross section of the drawing, and a term the “top,” the “upper portion,” the “upper surface,” or the like, indicates its opposite direction. However, these directions are defined for convenience of explanation, the claims are not particularly limited by the directions defined as described above, and concepts of upper/lower or left/right portions may be exchanged with each other.

In the present disclosure, connection between two components conceptually includes their indirect connection through an adhesive layer or the like as well as their direct connection. In addition, an expression, “electrically connected,” conceptually includes a physical connection and a physical disconnection. In addition, a term such as “first” or “second,” is used only to distinguish an element from another element, and may not limit the sequence or importance of the element. In some cases, a first element may be referred to as a second element without departing from the scope of the claims set forth herein. Similarly, a second element may also be referred to as a first element.

The expression, “an exemplary embodiment,” used herein does not refer to the same exemplary embodiment, and is provided to emphasize each particular feature different from that of another exemplary embodiment. However, the exemplary embodiments provided herein may be implemented in combination with features of another exemplary embodiment. For example, the content described in a specific exemplary embodiment may be understood as a description related to another exemplary embodiment unless an opposite or contradictory description is provided therein even if a content is not described in another exemplary embodiment.

The terms used herein are used only to describe an exemplary embodiment rather than limit the present disclosure. Here, a term of a singular number includes its plural number unless explicitly interpreted otherwise in context.

While the exemplary embodiments have been shown and described above, it will be apparent to those skilled in the art that modifications and variations could be made without departing from the scope of the present disclosure as defined by the appended claims.

What is claimed is:

1. A semiconductor package comprising:
a package board;
a first semiconductor chip disposed on the package board, and having a first recess portion adjacent to a first front surface of the first semiconductor chip facing the package board;
a second semiconductor chip disposed side by side with the first semiconductor chip on the package board, and having a second recess portion adjacent to a second front surface of the second semiconductor chip facing the package board; and
an interconnect bridge disposed on the first and second front surfaces, and at least partially disposed in each of the first and second recess portions.

2. The semiconductor package of claim 1, wherein the first and second recess portions respectively extend through portions of the first and second semiconductor chips from the first and second front surfaces in a vertical direction, and are respectively exposed from inner surfaces of the first and second semiconductor chips facing each other in a horizontal direction.

3. The semiconductor package of claim 2, further comprising a molding material at least partially filling a space between the first and second semiconductor chips,
wherein a third recess portion is disposed in a bottom of the molding material, and
the first and second recess portions are connected to each other through the third recess portion.

4. The semiconductor package of claim 3, wherein the molding material covers an outer surface of each of the first and second semiconductor chips, and
a lower surface of the molding material has a step by the third recess portion.

5. The semiconductor package of claim 3, further comprising a plurality of first contact members connecting the first or second semiconductor chip or the interconnect bridge to the package board; and
an insulating material disposed to fill a space between at least one of the molding material, the first or second semiconductor chip, or the interconnect bridge and the package board, and covering the plurality of first contact members.

6. The semiconductor package of claim 5, wherein each of the plurality of first contact members includes a metal post.

7. The semiconductor package of claim 1, further comprising a plurality of second contact members respectively connecting the interconnect bridge to the first and second semiconductor chips.

8. The semiconductor package of claim 7, wherein each of the plurality of second contact members includes at least one of a metal bump or a solder bump.

9. The semiconductor package of claim 1, wherein the interconnect bridge is directly connected to each of the first and second semiconductor chips.

10. The semiconductor package of claim 1, wherein the interconnect bridge is in direct contact with each of the first and second semiconductor chips through a recessed surface of the first or second recess portion.

11. A semiconductor package comprising:
a package board;
first and second semiconductor chips disposed on the package board;
a molding material disposed on the package board, and at least partially filling a space between the first and second semiconductor chips;
a recess portion extending through a portion of each of the first and second semiconductor chips and the molding material in a vertical direction from a lower surface of each of the first and second semiconductor chips and the molding material; and
an interconnect bridge disposed in the recess portion.

12. The semiconductor package of claim 11, wherein the recess portion has a bottom surface including the lower surface of each of the first and second semiconductor chips and the molding material, and a wall surface including an inner surface of each of the first and second semiconductor chips, and
the bottom surface of the recess portion is substantially flat.

13. The semiconductor package of claim 11, wherein the first semiconductor chip includes a first semiconductor board, a plurality of first transistor elements disposed on the first semiconductor board, a first insulating layer disposed on the first semiconductor board, and a plurality of first metal layers respectively disposed on or in the first insulating layer,
the second semiconductor chip includes a second semiconductor board, a plurality of second transistor elements disposed on the second semiconductor board, a second insulating layer disposed on the second semiconductor board, and a plurality of second metal layers respectively disposed on or in the second insulating layer, and
the plurality of first and second metal layers respectively include a plurality of first and second contact pads, each of which is at least partially exposed from a lower surface of each of the first and second insulating layers.

14. The semiconductor package of claim 13, wherein the interconnect bridge includes an organic insulating layer, a plurality of metal wiring layers respectively disposed on or in the organic insulating layer, and at least one metal via layer disposed in the organic insulating layer and connecting the plurality of metal wiring layers to each other,
the metal wiring layers disposed on the uppermost and lowermost sides of the plurality of metal wiring layers respectively include a plurality of first and second connection pads, and
at least some portions of the plurality of first and second contact pads are respectively connected to the plurality of first connection pads.

15. The semiconductor package of claim 14, wherein at least some other portions of the plurality of first and second contact pads and the plurality of second connection pads are respectively connected to the package board by using a plurality of first contact members, and
the plurality of first contact members are embedded in an insulating material.

16. The semiconductor package of claim 15, wherein at least some portions of the plurality of first and second contact pads are respectively connected to the plurality of first connection pads by using a plurality of second contact members.

17. The semiconductor package of claim 15, wherein at least some portions of the plurality of first and second contact pads are directly connected to the plurality of first connection pads, respectively.

18. The semiconductor package of claim 15, wherein at least some portions of the plurality of first and second contact pads are in direct contact with the plurality of first connection pads, respectively.

19. The semiconductor package of claim 15, wherein at least some other portions of the plurality of first and second contact pads and the plurality of second connection pads are disposed on the same surface of the insulating material.
